(19) United States
(12) Patent Application Publication
(10) Pub. No.: US 2026/0082499 A1
(43) Pub. Date: Mar. 19, 2026

(54) DISPLAY DEVICE

(71) Applicant: Sharp Display Technology Corporation, Kameyama City (JP)

(72) Inventors: Hirotoshi YASUNAGA, Kameyama City (JP); Hisashi Watanabe, Kameyama City (JP)

(21) Appl. No.: 19/333,630

(22) Filed: Sep. 19, 2025

(30) Foreign Application Priority Data
Sep. 19, 2024 (JP) 2024-162333

(51) Int. Cl. H05K 5/03

(52) U.S. Cl. CPC H05K 5/03

(57) ABSTRACT

A display device including a display panel, a housing that stores the display panel and includes a bezel placed around the display panel in a plan view, a front plate that is placed on a viewing side of the display panel and overlaps the display panel and at least part of the bezel in a plan view, and an adhesive member that is placed between the bezel and the front plate, in which the adhesive member includes a first adhesive layer, and the first adhesive layer is at least partially in contact with the front plate and has a space between the first adhesive layer and the front plate, or contains bubbles inside the first adhesive layer.

### CROSS-REFERENCE TO RELATED APPLICATIONS

This application claims the benefit of priority to Japanese Patent Application Number 2024-162333 filed on Sep. 19, 2024. The entire contents of the above-identified application are hereby incorporated by reference.

### BACKGROUND

### Technical Field

The disclosure relates to a display device.

In recent years, studies have been conducted on ways to improve design of display devices that display desired images when a display screen is on, by making a display panel inconspicuous by harmonizing with surrounding components, a housing, and the like when the display device is off.

For example, JP 5725581 B discloses a printed matter including a base film, a first color pattern layer provided on the base film and including multiple first color dots, a second color pattern layer provided on the first color pattern layer and including multiple second color dots, and a third color pattern layer provided on the second color pattern layer and including multiple third color dots, in which each of the first color dots includes a first color binder and multiple first color pigment chips dispersed inside the first color binder, each of the second color dots includes a second color binder and multiple second color pigment chips dispersed inside the second color binder, each of the third color dots includes a third color binder and multiple third color pigment chips dispersed inside the third color binder, each of the first color pigment chip, the second color pigment chip, and the third color pigment chip is any one of a red interference pigment, a green interference pigment, and a blue interference pigment that develops a color as interference light on a reflected light side, and the interference light is additively mixed, and discloses that the printed matter can be used in a display device.

### SUMMARY

The printed matter disclosed in JP 5725581 B is provided with a transmissive smoke printed layer, and when the printed matter is bonded to a display device, transmittance may be lowered. In addition, in the related art, when a front plate and a bezel of a housing are bonded together with an adhesive layer or the like, an appearance of a bonded portion where the adhesive layer or the like is placed is different from an appearance of a non-bonded portion where the adhesive layer or the like is not placed, and the bonded portion may be noticeable.

An object of the disclosure is to provide a display device in which a bonded portion where a bezel and a front plate are bonded together with an adhesive member is not noticeable.
(1) A display device according to an embodiment of the disclosure includes a display panel, a housing configured to store the display panel and including a bezel placed around the display panel in a plan view, a front plate placed on a viewing side of the display panel and overlapping the display panel and at least part of the bezel in a plan view, and an adhesive member placed between the bezel and the front plate, in which the adhesive member includes a first adhesive layer, the first adhesive layer being at least partially in contact with the front plate and having a space between the first adhesive layer and the front plate, or containing bubbles inside the first adhesive layer.
(2) In a display device according to an embodiment of the disclosure, in addition to the configuration in (1), the adhesive member further includes a base material placed on a bezel side of the first adhesive layer.
(3) In a display device according to an embodiment of the disclosure, in addition to the configuration in (1) or (2), the adhesive member further includes a second adhesive layer on the bezel side of the base material.
(4) In a display device according to an embodiment of the disclosure, in addition to the configuration in (3), the second adhesive layer is an adhesive layer being partially in contact with the base material and including a space between the second adhesive layer and the base material.
(5) In a display device according to an embodiment of the disclosure, in addition to any one of the configurations in (1) to (4), the adhesive member includes a region where the space passes through the first adhesive layer in a thickness direction.
(6) In a display device according to an embodiment of the disclosure, in addition to the configuration in (3) or (4), the adhesive member includes a region where the space passes through the second adhesive layer in a thickness direction.
(7) In a display device according to an embodiment of the disclosure, in addition to any one of the configurations in (1) to (6), the first adhesive layer includes multiple recessed portions or protruding portions on a surface on a bezel side.
(8) In a display device according to an embodiment of the disclosure, in addition to any one of the configurations in (3), (4), and (6), the first adhesive layer is provided with the space along a first direction on a surface on a front plate side, and the second adhesive layer is provided with the space along a direction different from the first direction in a plan view on a surface on the front plate side.
(9) In a display device according to an embodiment of the disclosure, in addition to any one of the configurations in (3), (4), (6), and (8), the second adhesive layer includes a region, the region not overlapping the first adhesive layer in a plan view.
(10) In a display device according to an embodiment of the disclosure, in addition to any one of the configurations in (1) to (9), the front plate has a total light transmittance of 5% or more.
(11) In a display device according to an embodiment of the disclosure, in addition to any one of the configurations in (1) to (10), the front plate includes a design layer.
(12) In a display device according to an embodiment of the disclosure, in addition to any one of the configurations in (1) to (11), the bezel has a reflectance of 50% or less.
(13) A display device according to an embodiment of the disclosure includes, in addition to any one of the configurations in (1) to (12), a component between the bezel and the front plate, the component being identical to a component on the viewing side of the display panel.
(14) In a display device according to an embodiment of the disclosure, in addition to any one of the configurations in (1) to (13), local dimming is possible.

According to the disclosure, it is possible to provide a display device in which a bonded portion where a bezel and a front plate are bonded together with an adhesive member is not noticeable.

### BRIEF DESCRIPTION OF DRAWINGS

The disclosure will be described with reference to the accompanying drawings, wherein like numbers reference like elements.

FIG. 1 is a schematic plan view of a display device according to a first embodiment.

FIG. 2 is a schematic cross-sectional view taken along line X1-X2 in FIG. 1.

FIG. 3 is an enlarged schematic cross-sectional view of a bonded portion of a bezel and a front plate surrounded by a dotted line in FIG. 2.

FIG. 4 is an enlarged schematic cross-sectional view of an adhesive member surrounded by a dotted line in FIG. 3, illustrating an example of an adhesive member 400 in which a space 401a does not pass through a first adhesive layer 401 in a thickness direction.

FIG. 5 is an enlarged schematic cross-sectional view of an adhesive member surrounded by a dotted line in FIG. 3, illustrating an example of an adhesive member 400 having a region where a space 401a passes through a first adhesive layer 401 in a thickness direction.

FIG. 6 is a schematic plan view illustrating a first plan view of an adhesive member 400 illustrated in FIG. 5.

FIG. 7 is a schematic plan view illustrating a second plan view of the adhesive member 400 illustrated in FIG. 5.

FIG. 8 is a schematic plan view illustrating a third plan view of the adhesive member 400 illustrated in FIG. 5.

FIG. 9 is a schematic cross-sectional view illustrating a first modified example of the first embodiment.

FIG. 10 is a schematic cross-sectional view illustrating a second modified example of the first embodiment.

FIG. 11 is a schematic cross-sectional view illustrating a third modified example of the first embodiment.

FIG. 12 is a schematic cross-sectional view illustrating a fourth modified example of the first embodiment, illustrating a case in which spherical particles are glass beads 501.

FIG. 13 is a schematic cross-sectional view illustrating the fourth modified example of the first embodiment, illustrating a case in which spherical particles are hollow beads 502.

FIG. 14 is a schematic plan view illustrating a fifth modified example of the first embodiment, describing a case in which an image is displayed on a display device capable of local dimming.

FIG. 15 is an enlarged schematic cross-sectional view of a display device according to a second embodiment, illustrating an adhesive portion of a bezel 310 and a front plate 110, and surroundings thereof.

FIG. 16 is a schematic plan view of the display device according to the second embodiment.

FIG. 17 is a schematic cross-sectional view illustrating an example of an adhesive member 400 including a second adhesive layer 403.

FIG. 18 is a schematic cross-sectional view illustrating an example of an adhesive member 400 including a second adhesive layer 403 and a second base material 404.

FIGS. 19A, 19B, and 19C illustrate schematic plan views describing an example of a method of layering a first adhesive layer 401 and the second adhesive layer 403 illustrated in FIG. 17 or 18.

FIG. 20 is a schematic cross-sectional view illustrating an example of an adhesive member 400 included in a display device according to a fourth embodiment.

FIG. 21 is a schematic cross-sectional view illustrating another example of an adhesive member 400 included in a display device according to the fourth embodiment.

FIG. 22 is a schematic cross-sectional view of a display device according to a fifth embodiment.

FIG. 23 is a schematic plan view of the display device according to the fifth embodiment.

FIG. 24 is a schematic plan view of a typical display device according to a first comparative embodiment.

FIG. 25 is a schematic cross-sectional view of the typical display device according to the first comparative embodiment.

FIG. 26 is an enlarged schematic cross-sectional view for describing reflection of external light in a region surrounded by a dotted line in FIG. 25.

FIG. 27 is a schematic plan view of a typical display device according to a second comparative embodiment.

FIG. 28 is a schematic cross-sectional view of the typical display device according to the second comparative embodiment.

FIG. 29 is an enlarged schematic cross-sectional view for describing reflection of external light in a region surrounded by a dotted line in FIG. 28.

FIG. 30 is a schematic plan view of a typical display device according to a third comparative embodiment.

FIG. 31 is a schematic cross-sectional view of the typical display device according to the third comparative embodiment.

FIG. 32 is an enlarged schematic cross-sectional view for describing reflection of external light in a region surrounded by a dotted line in FIG. 31.

FIG. 33 is a schematic plan view of a typical display device, describing an aspect in which a front plate includes a design layer.

### DESCRIPTION OF EMBODIMENTS

The disclosure will be described in detail below through the presentation of embodiments with reference to the drawings; however, the disclosure is not limited only to these embodiments. In the following description, the same reference numerals will be appropriately used in common among the different drawings for the same parts or parts having similar functions, and repeated description thereof will be omitted as appropriate. Each of the aspects of the disclosure may be combined as appropriate within a scope that does not depart from the gist of the disclosure.

In this specification, when two directions (planes) are orthogonal to each other, an angle between the two directions (planes) is preferably in a range of 90°±3°, more preferably in a range of 90°±1°, and even more preferably in a range of 90°±0.5°. When two directions (planes) are parallel, an angle between the two directions (planes) is preferably in a range of 0°±3°, more preferably in a range of 0°±1°, and even more preferably in a range of 0°±0.5°.

In this specification, when a target component is placed facing a viewer, a viewing side means a side closer to the viewer relative to the target component, and a back side means a side farther from the viewer relative to the target component. In this specification, plan view means a view from the viewing side.

In this specification, a display device being on refers to a state in which light is emitted from the viewing side of the display device. When a display panel is a liquid crystal panel, a display device being on refers to a state in which a backlight placed on a back side of the liquid crystal panel is on and the liquid crystal panel transmits light (white display state), and when the display panel is a self-luminous panel such as an OLED, a display device being on refers to a state in which the display panel is on. A display device being an off state refers to a state in which no light is emitted from the viewing side of the display device. When the display panel is a liquid crystal panel, the display device being off state refers to a state in which a backlight is off, and a state in which backlights corresponding to regions (black display regions) of the display panel where no image is being displayed are off in a display device equipped with backlights that can be locally dimmed. When the display panel is a self-luminous panel such as an OLED panel, the display device being off state refers to a state in which the display panel is an off state.

### First Embodiment

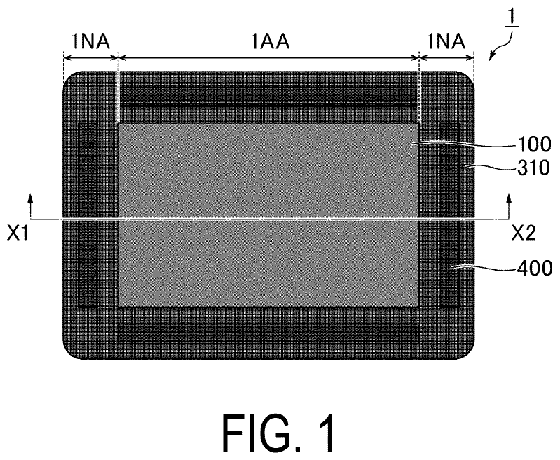

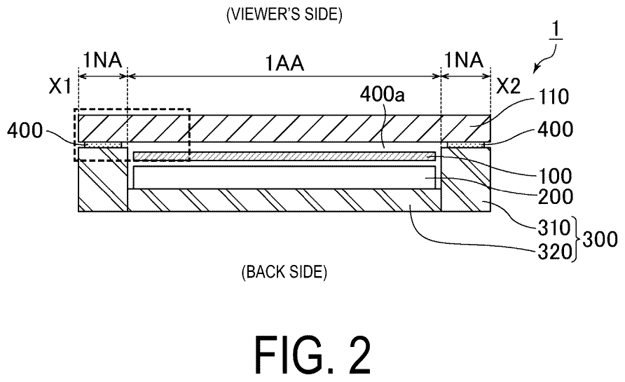

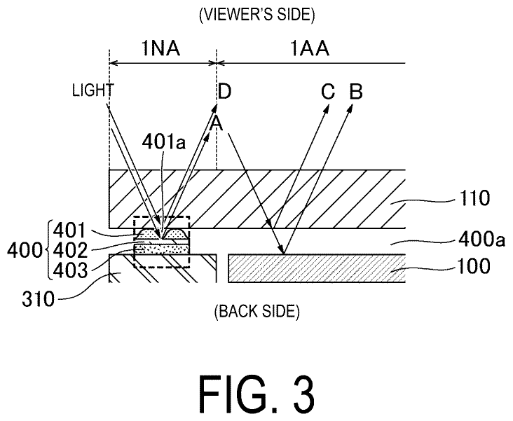

FIG. 1 is a schematic plan view of a display device according to a first embodiment. FIG. 2 is a schematic cross-sectional view taken along line X1-X2 in FIG. 1. FIG. 3 is an enlarged schematic cross-sectional view of a bonded portion of a bezel and a front plate surrounded by a dotted line in FIG. 2. A display device 1 according to the present embodiment includes a display panel 100, a housing 300 that stores the display panel 100 and includes a bezel 310 that is placed around the display panel 100 in a plan view, a front plate 110 that is placed on a viewing side of the display panel 100 and overlaps the display panel 100 and at least part of the bezel 310 in a plan view, and an adhesive member 400 that is placed between the bezel 310 and the front plate 110.

### Housing

As illustrated in FIG. 2, the display device 1 includes the housing 300 that stores the display panel 100. The housing 300 includes a bottom 320 and the bezel 310 that is provided around the bottom 320 and protrudes toward the viewing side. In a plan view, the bottom 320 overlaps the display panel 100, and the bezel 310 is placed around the display panel 100. For example, by placing the adhesive member 400 on the back side of the front plate 110 overlapping a frame region 1NA and bonding the adhesive member 400 to the bezel 310, the front plate 110 can be fixed to the housing 300. A face of the bezel 310 is preferably horizontal on the viewing side, and the bezel 310 is bonded to the front plate 110 with the adhesive member 400 on the horizontal face.

The housing 300 may store, for example, a circuit substrate (not illustrated) on which a drive circuit for driving the display panel 100 and a backlight 200 is formed. The housing 300 is not particularly limited as long as the display panel 100 and the front plate 110 can be stored therein, and may be made of metal or resin. A shape of the housing 300 is not limited to a box shape with an open top as illustrated in FIG. 2. The bottom 320 and the bezel 310 may be integrally formed.

### Display Panel

As illustrated in FIG. 1, the display panel 100 has, in a plan view, a display region 1AA and the frame region 1NA placed around the display region 1AA. The frame region 1NA is a region that overlaps the bezel 310 in a plan view and is a region that is not involved in displaying images and the like on the display device. The display region 1AA is a region that overlaps the display panel 100 in a plan view. The display region 1AA is specifically a region including multiple pixels, and is a region where desired images and the like are displayed during transmissive display.

Examples of the display panel 100 include a liquid crystal panel and a self-luminous panel such as an OLED panel. The liquid crystal panel is composed of, for example, a pair of substrates and a liquid crystal layer that is sandwiched between the pair of substrates and contains liquid crystal molecules. The pair of substrates may be a TFT substrate including multiple switching elements such as thin film transistors (TFTs) and a counter substrate. The TFT substrate or the counter substrate may include color filters of red, green, blue, or the like that overlap pixels described below.

The TFT substrate may be composed of a support substrate, gate wiring lines and source wiring lines intersecting the gate wiring lines placed on the support substrate, TFTs placed near intersections of the gate wiring lines and the source wiring lines, and pixel electrodes electrically connected to the TFTs. A region surrounded by the gate wiring lines and the source wiring lines is the pixel, and the color filters are arranged so as to overlap the corresponding pixels.

A common electrode is placed on the TFT substrate or the counter substrate. By applying a predetermined voltage between the pixel electrode and the counter electrode, an electrical field is generated in the liquid crystal layer, and an orientation direction of the liquid crystal molecules is controlled to adjust an amount of transmission of light emitted from the backlight 200 to the liquid crystal panel, thereby providing transmissive display.

The liquid crystal panel includes a pair of polarizers on the viewing side and the back side. The pair of polarizers may be absorptive linear polarizers each having a transmission axis that transmits only light in a specific polarization direction and an absorption axis orthogonal to the transmission axis. The pair of polarizers are arranged, for example, in crossed Nicols such that the transmission axes thereof are orthogonal to each other. In addition, between the TFT substrate and the liquid crystal layer, and between the counter substrate and the liquid crystal layer, an alignment film that controls the orientation direction of the liquid crystal molecules when no voltage is applied may be placed.

An example of the self-luminous panel is an organic light emitting diode (OLED) panel including multiple OLEDs. The self-luminous panel is a panel that can emit light by itself with light-emitting elements such as OLEDs inside the panel, and can emit light to the viewing side without requiring an external light source such as a backlight.

A configuration of the organic light emitting diode is not particularly limited, and may be a configuration in which a cathode electrode, a light-emitting layer, and an anode electrode are layered in this order. The light-emitting layer may contain a fluorescent material, a phosphorescent material, or the like as a luminescent material. An electron transport layer may be placed between the cathode electrode and the light-emitting layer, and a hole transport layer may be placed between the light-emitting layer and the anode electrode.

The light-emitting elements such as OLEDs may be arranged in a matrix on a substrate on which, for example, gate wiring lines, source wiring lines, TFTs, and the like are formed, so that each TFT (each pixel) includes one light-emitting element. In the OLED panel, a region where multiple light-emitting elements are arranged is the display region. The multiple light-emitting elements may include red light-emitting elements, green light-emitting elements, and blue light-emitting elements. The self-luminous panel may include a circular polarizer on a front plate side (front side) from the viewpoint of reducing internal reflectance.

On the front side of the display panel 100, an anti-reflection film may be further placed on the front side of the polarizer such as the linear polarizer or the circular polarizer described above. Examples of the anti-reflection film include known films such as an anti-reflection film (AR film) and an anti-glare film (AG film). As the AR film, for example, an AR film manufactured by Nitto Denko Corporation can be used. As the AG film, for example, an AG film manufactured by Nitto Denko Corporation can be used.

### Front Plate

The front plate 110 is a component placed on the front side (viewing side) of the display panel 100, and transmits at least part of light incident from the display panel 100. The front plate 110 preferably includes a transparent base material (transparent base material 111 described below).

The transparent base material may be, for example, a plate made of resin such as acrylic or polycarbonate, or a glass plate. The transparent base material may have a flat surface or a curved surface.

From the viewpoint of maintaining high luminance of the display device, the transparent base material preferably has a high transmittance, for example, a transmittance of 90% or more. From the viewpoint of suppressing blurring of display images, the transparent base material preferably has a haze of 10% or less. In this specification, the transmittance refers to a total light transmittance, and is measured by a method in accordance with JIS K 7361-1:1997. The total light transmittance is a total light transmittance in a visible light region (e.g., wavelengths from 380 nm to 780 nm). The haze is measured by a method in accordance with JIS K 7136:2000. The total light transmittance can be measured, for example, using a turbidity meter such as “Haze Meter NDH 2000” manufactured by Nippon Denshoku Industries Co., Ltd. The haze can be measured, for example, using a turbidity meter such as “Haze Meter NDH 2000” manufactured by Nippon Denshoku Industries Co., Ltd.

A transmittance of a region of the front plate 110 that overlaps the display region 1AA is preferably 50% or more. With this aspect, the display device 1 can perform transmissive display while maintaining high luminance. When the transmittance of the region of the front plate 110 that overlaps the display region 1AA is less than 50%, the luminance of the display device 1 may decrease, and display images may be difficult to see in a bright environment. The transmittance of the region of the front plate 110 that overlaps the display region 1AA is more preferably 70% or more. An upper limit of the transmittance of the front plate 110 is, for example, 90%.

The front plate 110 preferably has a total light transmittance of 5% or more. As described below, the front plate 110 may include regions having different transmittances in an in-plane direction, but a total light transmittance of a region of the front plate 110 having the lowest transmittance, including a region overlapping the frame region 1NA and a region overlapping the display region 1AA of the front plate 110, is preferably 5% or more. In other words, it is preferable that the front plate 110 do not include a frame print portion or a structure that completely blocks light even in the frame region 1NA of the display panel in a plan view. The frame print portion may be a light blocking layer formed of, for example, black ink. As described below, a transmissive design layer may be provided, but even when the design layer is provided, it is preferable that the total light transmittance of the region of the front plate 110 having the lowest transmittance be 5% or more.

As illustrated in FIG. 3, the adhesive member 400 is placed between the bezel 310 and the front plate 110. In the first embodiment, the adhesive member 400 includes a first adhesive layer 401 that is partially in contact with the front plate 110 and has a space 401a between the first adhesive layer 401 and the front plate 110. In the first embodiment, since only part of the adhesive member 400 is in contact with the front plate 110, an area in contact with the front plate 110 can be reduced compared with when an entire surface of the adhesive member 400 is in contact with the front plate 110. Therefore, the bonded portion with the adhesive member 400 can be made less noticeable.

The bezel 310 and the front plate 110 may be directly bonded together with the adhesive member 400, or may be bonded together with the adhesive member 400 and another adhesive layer, a double-sided tape, or the like. When the adhesive member 400 is used for direct bonding, it is preferable that the adhesive member 400 further include an adhesive layer on the back side thereof. In this case, the back side of the adhesive member 400 is preferably in contact with the bezel 310. The front plate 110 has a larger area than the display panel 100 in a plan view, and is bonded to the bezel 310 at a portion outside the display panel in a plan view.

In FIG. 3, A denotes a surface reflectance of a first base material 402, B denotes a surface reflectance of the display panel 100, C denotes an interface reflectance between the front plate 110 and an air layer 400a in the display region 1AA, and D denotes an interface reflectance between the front plate 110 and the air layer 400a at the bonded portion where the adhesive member is placed in the frame region 1NA. C and D are the same because they are the interface reflectances between the same front plate 110 and the same air layer 400a. Therefore, in principle, by adjusting the surface reflectance A of the first base material 402 so that A+D=B+C, that is, A=B, a boundary between the display region 1AA and the bonded portion can be made less visible. In the display device 1 according to the first embodiment, interface reflection occurs also at an interface between the space 401a and the first adhesive layer 401, so that an appearance of the bonded portion is closer to an appearance of the display region 1AA, and the boundary between the display region 1AA and the bonded portion can be made less visible.

A thickness of the first adhesive layer 401 is preferably from 10 μm to 500 μm, more preferably from 10 μm to 300 μm, still more preferably from 10 μm to 100 μm, and particularly preferably from 10 μm to 50 μm. When the adhesive member 400 includes the first base material 402, the thickness of the first adhesive layer 401 is a distance from a surface of the first base material 402 on the viewing side to a face in contact with the front plate 110.

An acrylic adhesive or the like can be used for the first adhesive layer 401. The first adhesive layer 401 is preferably transparent, and a total light transmittance thereof is preferably 80% or more, and more preferably 90% or more.

The adhesive member 400 only needs to be placed so as not to extend outside the bezel 310 in a plan view. For example, the adhesive member 400 may be placed so as to surround the display panel 100, or may be divided into multiple pieces and placed on the bezel 310.

A width of the adhesive member 400 may be narrower than a width of the bezel 310. In a plan view, the width of the adhesive member 400 is, for example, from 300 μm to 2.0 cm.

A thickness of the adhesive member 400 is preferably from 50 μm to 1 mm, more preferably from 50 μm to 500 μm, and still more preferably from 50 μm to 100 μm. The thickness of the adhesive member 400 is a distance from a face of a component included in the adhesive member 400 that is in contact with the bezel 310 to a face of the first adhesive layer 401 that is in contact with the front plate 110.

The adhesive member 400 preferably further includes a base material 402 (hereinafter, also referred to as a first base material) placed on the bezel 310 side of the first adhesive layer 401. The first base material 402 is preferably a transparent base material, and for example, a base material of resin such as acrylic, polyethylene terephthalate (PET), or polycarbonate can be used. A total light transmittance of the first base material 402 is preferably 80% or more, and more preferably 90% or more.

A thickness of the first base material 402 is preferably from 25 μm to 300 μm, and more preferably from 25 μm to 50 μm.

The adhesive member 400 may further include a second adhesive layer 403 on the bezel side of the first base material 402. In other words, the adhesive member 400 may be a double-sided tape in which the first adhesive layer 401, the first base material 402, and the second adhesive layer 403 are layered in this order from the viewing side. The second adhesive layer 403 may be made of a material similar to that of the first adhesive layer 401. The first embodiment illustrates a case in which an entire surface of the second adhesive layer 403 is in contact with the first base material 402 without a space 403a. However, as described below, the second adhesive layer 403 may be partially in contact with the first base material 402 and may have the space 403a between the second adhesive layer 403 and the first base material 402.

A thickness of the second adhesive layer 403 is preferably from 50 μm to 1 mm, more preferably from 50 μm to 500 μm, and still more preferably from 50 μm to 100 μm. The thickness of the second adhesive layer 403 is, when at least part of the second adhesive layer 403 is in contact with the bezel 310, a distance from the surface of the bezel 310 on the viewing side to a face in contact with the first base material 402, and is, when the adhesive member 400 includes a second base material 404 described below, a distance from a surface of the second base material 404 on the viewing side, with which at least part of the second adhesive layer 403 is in contact, to a face in contact with the first base material 402.

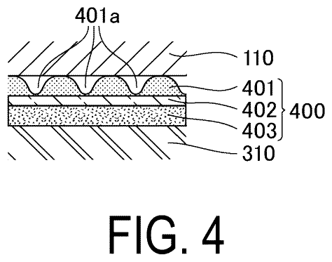

FIG. 4 is an enlarged schematic cross-sectional view of an adhesive member surrounded by a dotted line in FIG. 3, illustrating an example of an adhesive member 400 in which a space 401a does not pass through a first adhesive layer 401 in a thickness direction. As illustrated in FIG. 4, the space 401a does not have to pass through the first adhesive layer 401 in the thickness direction, and the first adhesive layer 401 may have multiple recessed portions or protruding portions on a surface on the bezel 310 side.

The multiple recessed portions or protruding portions may be arranged along a first direction D1, and may be further arranged along a second direction D2. The second direction D2 is a direction different from the first direction D1, and forms an angle of, for example, from 15° to 165° relative to the first direction D1.

Examples of a planar shape of the recessed portions or the protruding portions include a circle (dot pattern), an ellipse, and a polygon such as a rectangle and a rhombus. The first adhesive layer 401 may have linear recessed portions or protruding portions extending along the first direction D1 and/or the second direction D2. Examples of the linear recessed portions or protruding portions include semicylinders and triangular prisms. The recessed portions or the protruding portions are obtained, for example, by printing a pattern of an adhesive composition on the surface of the first base material 402.

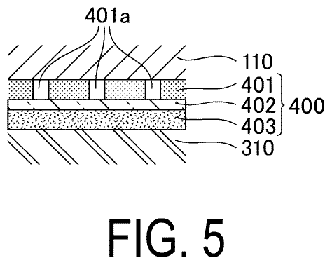

FIG. 5 is an enlarged schematic cross-sectional view of an adhesive member surrounded by a dotted line in FIG. 3, illustrating an example of an adhesive member 400 has a region where a space 401a passes through a first adhesive layer 401 in a thickness direction. The first adhesive layer 401 may be divided. In other words, as illustrated in FIG. 5, the adhesive member 400 may have a region where the space 401a passes through the first adhesive layer 401 in the thickness direction. The first adhesive layer 401 includes multiple adhesive portions divided by the region that passes through the first adhesive layer 401 in the thickness direction. Focusing only on the adhesive member 400, the first base material 402 is exposed in the region where the space 401a passes through the first adhesive layer 401.

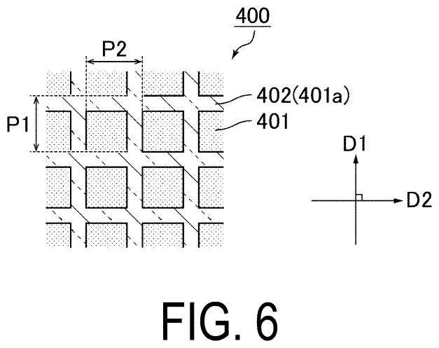

FIG. 6 is a schematic plan view illustrating a first plan view of an adhesive member 400 illustrated in FIG. 5. The first adhesive layer 401 may include multiple adhesive portions arranged along the first direction D1, and may further include multiple adhesive portions arranged along the second direction D2. FIG. 6 illustrates an example in which the second direction D2 is orthogonal to the first direction D1. The second direction D2 is not limited to the case in FIG. 6, and preferably forms an angle of from 15° to 165° relative to the first direction D1.

FIG. 6 illustrates an example in which a planar shape of multiple adhesive portions included in a first adhesive layer 401 is square. In FIG. 6, in a plan view, a space 401a is provided in a lattice pattern along the first direction D1 and the second direction D2. The planar shape of the adhesive portion is not limited to a specific shape, and may be a polygon such as a square, a rectangle, or a rhombus, a circle, an ellipse, or the like.

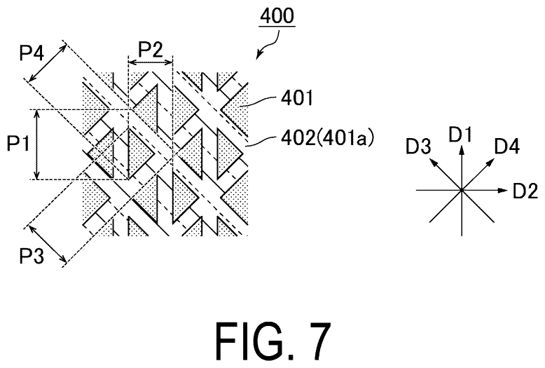

FIG. 7 is a schematic plan view illustrating a second plan view of the adhesive member 400 illustrated in FIG. 5. In FIG. 7, the space 401a is arranged along the first direction D1, and further along a third direction D3 rotated counterclockwise relative to the first direction D1 and a fourth direction D4 rotated clockwise relative to the first direction D1, and multiple adhesive portions are surrounded by corresponding portions of the space 401a. The multiple adhesive portions can also be said to be arranged along the second direction D2 orthogonal to the first direction D1, which is one of the directions in which the space 401a extends.

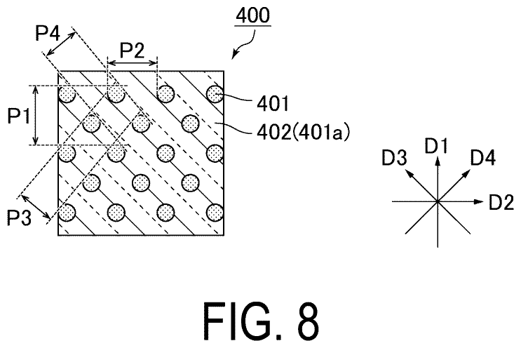

FIG. 8 is a schematic plan view illustrating a third plan view of an adhesive member 400 illustrated in FIG. 5. FIG. 8 illustrates an example in which a planar shape of multiple adhesive portions divided by a region passing through the first adhesive layer 401 in a thickness direction is circular. In FIG. 8, multiple circular adhesive portions are arranged along the first direction D1 and the second direction D2 that forms an angle with the first direction D1. The multiple adhesive portions can also be said to be arranged along the third direction D3 rotated counterclockwise relative to the first direction D1 and the fourth direction D4 rotated clockwise relative to the first direction D1.

When a period (pitch P) at which the adhesive portions are arranged is too large, an arrangement pattern of the multiple adhesive portions may be visible to a viewer. Therefore, from the viewpoint of making the arrangement pattern less noticeable, the pitch P is preferably 1 mm or less, and more preferably 0.5 mm or less. The pitch P is preferably, for example, 50 μm or more, and more preferably 100 μm or more. The pitch P refers to a unit distance of a repetition period of the adhesive portions and the space in the arrangement direction of the multiple adhesive portions. In FIG. 6, when the sum of a width of one adhesive portion 401 and a width of one portion of the space 401a in the first direction D1 and the second direction D2 is defined as a pitch P1 and a pitch P2, respectively, it is preferable that at least one of the pitch P1 and the pitch P2 be within the above numerical range, and it is more preferable that both the pitch P1 and the pitch P2 be within the above numerical range. In FIGS. 7 and 8, when the sum of a width of one adhesive portion 401 and a width of one portion of the space 401a in the first direction D1, the second direction D2, the third direction D3, and the fourth direction D4 is defined as pitches P1, P2, P3, and P4, respectively, it is preferable that at least one of the pitches P1 to P4 be within the above numerical range, and it is more preferable that all of the pitches P1 to P4 be within the above numerical range.

The region where the adhesive portions are arranged and the region where the space 401a passes through the first adhesive layer 401 in the thickness direction illustrated in FIGS. 6 to 8 may be reversed. For example, referring to FIG. 6, an adhesive portion may be arranged in a lattice pattern, and a planar shape of spaces 401a (portions where the first base material 402 is exposed) may be a square.

As described above, in the region where the first adhesive layer 401 is not in contact with the front plate 110, interface reflection between the air layer and the first adhesive layer 401 occurs. Therefore, the larger the area of the first adhesive layer 401 that is not in contact with the front plate 110, the closer the interface reflectance C and the interface reflectance D described in FIG. 3 can be, thereby making the boundary between the display region 1AA and the bonded portion less visible. On the other hand, from the viewpoint of increasing adhesive strength between the bezel 310 and the front plate 110, the area of the first adhesive layer 401 in contact with the front plate 110 is preferably larger. From these, a ratio of the area of the first adhesive layer 401 in contact with the front plate 110 to the total area of the bonded portion where the adhesive member 400 is placed is preferably from 20% to 80%, and more preferably from 20% to 50%. When the adhesive member 400 includes the first base material 402, the bonded portion refers to a region where the first base material 402 is placed in a plan view.

### Backlight

As illustrated in FIG. 2, the backlight 200 may be placed on the back side of the display panel 100. In particular, when the display panel 100 is a liquid crystal panel, the display device 1 preferably includes the backlight 200.

The backlight 200 may be any known type such as an edge-lit backlight in which light-emitting elements are arranged on an end face of a light guide plate, or a direct backlight in which a large number of light-emitting elements are arranged in a plane and uniformity is improved using a diffuser plate or the like. The light-emitting element may be any known type in the field of backlight such as a light emitting diode (LED), a fluorescent lamp, or a cold cathode tube.

### Display Method

When the display device 1 is on, light (display light) emitted from the display panel side passes through the front plate, is emitted to the viewing side, and provides transmissive display that allows the viewer to view any image and the like displayed on the display panel. When the display panel is a liquid crystal panel, the transmissive display can be performed by turning on the backlight while the liquid crystal panel is in a white display state. By aligning the liquid crystal molecules so as to form an angle with the transmission axis of the polarizer, a white display state is obtained in which light emitted from the backlight is transmitted to the viewing side, and when the orientation direction of the liquid crystal molecules forms an angle of 45° with the transmission axis of the polarizer, the transmittance is maximized. By aligning the liquid crystal molecules so as to be substantially parallel to the transmission axis of the polarizer, light transmitted to the viewing side is blocked by the liquid crystal layer even when the backlight is on, resulting in a black display state.

The bezel 310 preferably has a similar appearance to the display panel 100 when the display device 1 is off. To be specific, in a plan view, a region overlapping the display panel 100 is defined as the display region 1AA, and a region overlapping the bezel 310 is defined as the frame region 1NA, and when the display device 1 is off, an x value and a y value in an xy chromaticity diagram of the display region 1AA measured from the viewing side are defined as x_{α-1} and y_{α-1}, respectively, and an x value and a y value in an xy chromaticity diagram of the frame region 1NA measured from the viewing side are defined as x_{β-1} and y_{β-1}, respectively. Absolute values of a difference between x_{α-1} and x_{β-1} and a difference between y_{α-1} and y_{β-1} are both preferably 0.02 or less. The display device 1 having such an aspect can make a boundary between the bezel 310 and the display panel 100 even less visible, thereby achieving a better appearance.

The bezel 310 preferably has a reflectance of 50% or less, and more preferably 30% or less. The display panel 100 preferably has a reflectance of 50% or less and more preferably 30% or less when the display device 1 is off. The display device 1 having such an aspect can achieve a sober appearance without being too flashy. Note that the reflectance of the display panel 100 when the display device 1 is off is a reflectance of a viewing side face of the display panel 100 when the display device 1 is off. The reflectances of the bezel and the display panel are reflectances in a visible light region (e.g., wavelength 380 nm to 780 nm), and can be measured by a method in accordance with JIS R3106:2019. As a measurement device, a spectrophotometer (e.g., CM-700d manufactured by KONICA MINOLTA, INC.) can be used.

### First Modified Example

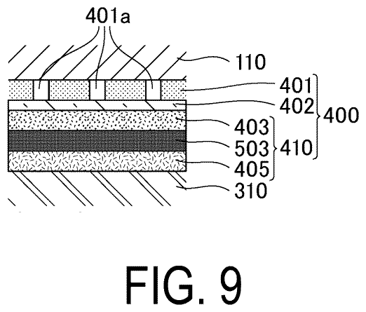

FIG. 9 is a schematic cross-sectional view illustrating a first modified example of the first embodiment. An adhesive member 400 may further include a second adhesive layer 403, a third base material 503, and a third adhesive layer 405 on a back side of a first base material 402 in this order from a viewing side. When a first adhesive layer 401 and the first base material 402 are regarded as a single-sided adhesive tape, and the second adhesive layer 403, the third base material 503, and the third adhesive layer 405 are regarded as a double-sided tape 410, it can be said that the single-sided adhesive tape including the first adhesive layer 401 and the bezel 310 are bonded together with the double-sided tape 410. As the double-sided tape with adhesive layers on both sides of the base material, for example, Double-faced Adhesive Tape for Fixing of LCD Components 3800 Series, manufactured by SEKISUI CHEMICAL CO., LTD can be used.

The third base material 503 is preferably black or gray. By making the third base material 503 black or gray, when the first adhesive layer 401, the first base material 402, and the second adhesive layer 403 are transparent or semi-transparent, an appearance of the third base material 503 affects an appearance, so that when the third base material 503 is dark, the appearance of the bonded portion can be made closer to the appearance of the display region 1AA. In the first modified example, the second adhesive layer 403 and/or the third adhesive layer 405 may be transparent, but may be black or gray like the third base material 503, and preferably have a reflectance of 50% or less. The reflectance of the adhesive layer can be measured in a similar manner to that for the bezel. Note that when the first adhesive layer 401, the first base material 402, and the second adhesive layer 403 are transparent, a face of the bezel 310 on the adhesive member 400 side is preferably a dark color such as black or gray.

### Second Modified Example

Since the first adhesive layer 401 is soft, a structure for maintaining the thickness of the adhesive member 400 may be provided between the front plate 110 and the bezel 310 in order to prevent the space 401a from being narrowed over time. Examples having a structure for maintaining the thickness of the adhesive member 400 will be described below as second to fourth modified examples with reference to the drawings.

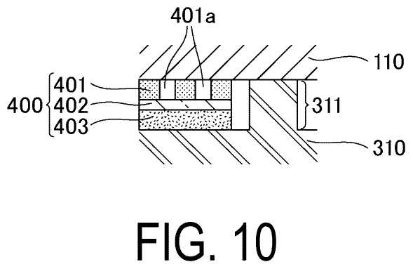

FIG. 10 is a schematic cross-sectional view illustrating the second modified example of the first embodiment. FIG. 10 and FIGS. 12 and 13 described below are enlarged schematic cross-sectional views of an adhesive portion between the bezel 310 and the front plate 110 and surroundings thereof. As illustrated in FIG. 10, in the second modified example, a housing (bezel 310) includes a pillar 311. The pillar 311 may be made of the same material as the bezel 310, for example, and may be made of metal or resin. A height of the pillar 311 is preferably the same as the thickness of the adhesive member 400 (in FIG. 10, the sum of a thickness of a first adhesive layer 401, a thickness of a first base material 402, and a thickness of a second adhesive layer 403). The pillar 311 may be positioned inside the adhesive member 400 (between the adhesive member 400 and a display panel 100) in a plan view, or may be positioned outside the adhesive member 400 in a plan view. The pillar 311 may be circular, elliptical, polygonal, or the like in a plan view. The pillar 311 may be placed along one side of the bezel or may be placed so as to surround the display panel 100.

### Third Modified Example

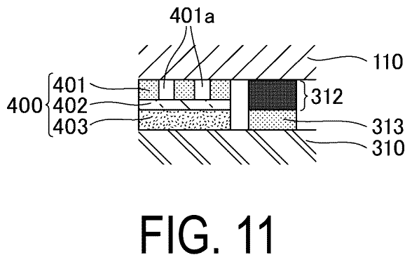

FIG. 11 is a schematic cross-sectional view illustrating a third modified example of the first embodiment. As illustrated in FIG. 11, the third modified example includes a spacer 312 between a bezel 310 and a front plate 110. The spacer 312 may be, for example, a columnar spacer, and examples of a planar shape include circular, elliptical, and polygonal. The spacer 312 may be made of resin, and any material that is usually used for spacers in the field of display panels can be used. An adhesive layer 313 may be placed between the spacer 312 and the bezel, and the sum of a thickness of the spacer 312 and a thickness of the adhesive layer 313 is preferably about the same as a thickness of an adhesive member 400 (in FIG. 11, the sum of a thickness of a first adhesive layer 401, a thickness of a first base material 402, and a thickness of a second adhesive layer 403).

### Fourth Modified Example

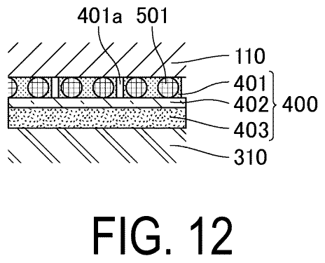

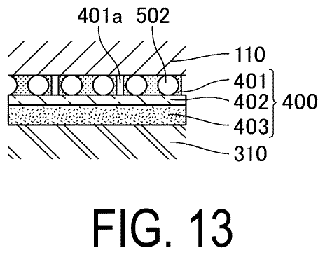

A first adhesive layer 401 may contain spherical particles. When the first adhesive layer 401 contains spherical particles, a thickness of the first adhesive layer 401 can be maintained. FIG. 12 is a schematic cross-sectional view illustrating a fourth modified example of the first embodiment, illustrating a case in which the spherical particles are glass beads 501. FIG. 13 is a schematic cross-sectional view illustrating the fourth modified example of the first embodiment, illustrating a case in which the spherical particles are hollow beads 502.

Examples of the spherical particles include resin particles such as acrylic resins and olefin resins, and particles of inorganic materials such as silica and glass. The spherical particles may be hollow particles that are hollow inside, or may be core-shell particles having a core and a shell layer covering the core. Hollow particles such as hollow beads can further reduce viewability of a bonded portion because the air inside the particle also causes interface reflection.

The particulate substance preferably has a mean particle size approximately equal to a thickness of the first adhesive layer 401, and is preferably from 10 μm to 500 μm, more preferably from 50 μm to 300 μm. The mean particle size means the 50% particle size in an integrated particle size distribution curve, and can be measured by a laser diffraction scattering method.

### Fifth Modified Example

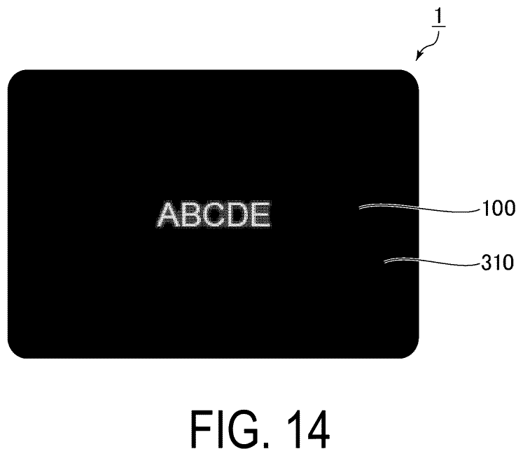

In a fifth modified example, a case will be described in which a display device 1 is capable of local dimming. FIG. 14 is a schematic plan view illustrating the fifth modified example of the first embodiment, and describes a case in which an image is displayed on a display device capable of local dimming. Note that in FIG. 14, difference in appearance between a display panel 100 and a bezel 310 is omitted.

The local dimming, also referred to as partial drive, is a display method in which the display region 1AA is divided into multiple regions (dimming areas) and luminance (light emission intensity) is adjusted for each region. An example of the display device 1 capable of local dimming is a display device further including a backlight 200 that is placed on a back side of the display panel 100 and is capable of local dimming.

The backlight 200 is preferably a direct backlight. As the backlight 200, an OLED panel including OLEDs as light-emitting elements may be used. The display device 1 further includes a luminance adjustment mechanism that adjusts luminance of the backlight 200. The luminance adjustment mechanism preferably adjusts light emission intensity of each of the multiple light-emitting elements for divided regions in accordance with a display image of the liquid crystal panel. Note that when an organic EL display is used as the display panel, pixels in an off state are displayed in black, resulting in an appearance similar to that of the backlight placed on the back side of the liquid crystal display being locally dimmed. The appearance is similar to when the backlight is used.

The local dimming can be used for achieving a sophisticated design of the display device 1 in which a picture (a string of letters ABCDE in FIG. 14) appears on a black background, as illustrated in FIG. 14. The local dimming changes brightness (luminance) of the backlight according to brightness of each dimming area of the display panel. In the dimming area where bright images and the like are displayed, the luminance of the backlight is increased, and in the dimming area where dark images and the like are displayed, the luminance of the backlight is decreased. In the dimming area where only black is displayed, the luminance of the backlight is further reduced or the backlight is turned off. In portions of the display region 1AA that are in a black display state, a good appearance can be achieved by turning off the backlight 200.

### Second Embodiment

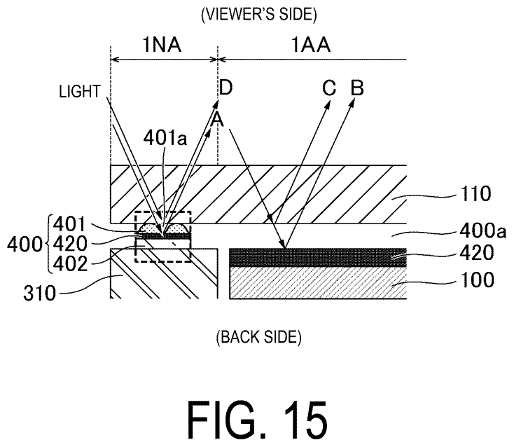

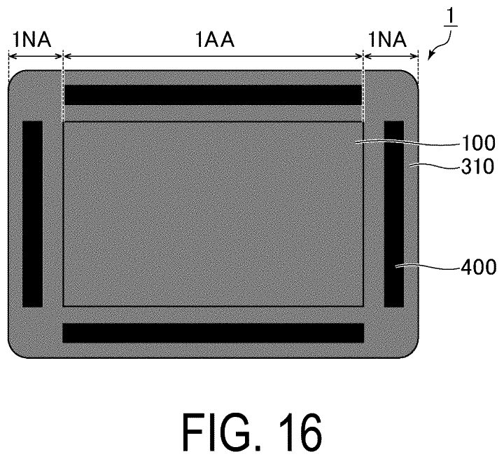

FIG. 15 is an enlarged schematic cross-sectional view of a display device according to a second embodiment, illustrating an adhesive portion of a bezel 310 and a front plate 110, and surroundings thereof. FIG. 16 is a schematic plan view of the display device according to the second embodiment. A display device 1 according to the second embodiment includes, between the bezel 310 and the front plate 110, a component that is the same as a component on a viewing side of a display panel 100. In a frame region 1NA, in a non-bonded portion where an adhesive member 400 is not placed, the bezel 310 and a surface of the display panel 100 in a display region 1AA are visible to a viewer. An appearance of the non-bonded portion is affected not only by interface reflection with an air layer but also by an appearance of a bezel surface. Therefore, when a material of the surface of the display panel 100 is different from a material of a surface of the bezel 310, appearances of the frame region 1NA and the display region 1AA are different from each other. In the second embodiment, by using the same material for the components underneath the front plate 110, the appearances of the frame region 1NA and the display region 1AA of the display device 1 can be made closer to each other, thereby improving appearance.

When the display panel 100 is a liquid crystal panel, a polarizer may be placed on the viewing side of the liquid crystal panel. When the polarizer is placed on the viewing side of the liquid crystal panel, a polarizer is preferably also placed between the bezel 310 and the front plate 110. Separate polarizers may be placed on the viewing side of the liquid crystal panel and between the bezel 310 and the front plate 110, or a single polarizer may be placed so as to cover both the bezel 310 and the display panel 100. When the separate polarizers are placed on the viewing side of the liquid crystal panel and between the bezel 310 and the front plate 110, it is preferable that the polarizer placed on the viewing side of the liquid crystal panel and the polarizer placed between the bezel 310 and the front plate 110 have the same in-plane polarization direction of, for example, a transmission axis and an absorption axis.

In addition, an AR film, an AG film, or the like may be further placed on the viewing side of the polarizer. In this case, a layered body of the polarizer and an AR film or a layered body of the polarizer and an AG film is preferably also placed between the bezel 310 and the front plate 110. Separate AR films or AG films may be placed on the viewing side of the liquid crystal panel and between the bezel 310 and the front plate 110, or a single AR film or AG film may be placed so as to cover both the bezel 310 and the display panel 100.

When the display panel is a self-luminous panel such as an OLED panel, a component of the display panel on the viewing side is, for example, a glass plate (glass substrate). In this case, a glass plate is preferably also placed between the bezel 310 and the front plate 110.

In FIG. 15, A denotes a surface reflectance of the polarizer placed between the bezel 310 and the front plate 110, B denotes a surface reflectance of the polarizer placed on the viewing side of the liquid crystal panel, C denotes an interface reflectance between the front plate 110 and an air layer 400a in the display region 1AA, and D denotes an interface reflectance between the front plate 110 and the air layer 400a in the bonded portion where the adhesive member is placed in the frame region 1NA. C and D are the same because they are the interface reflectances between the same front plate 110 and the same air layer 400a. A and B are the same. That is, A+D=B+C, so that as illustrated in FIG. 16, a boundary between the display region 1AA and the bonded portion is even less visible than in the first embodiment, resulting in a better appearance.

### Third Embodiment

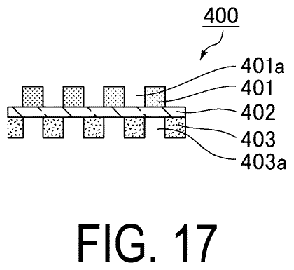

In the first embodiment, the adhesive member 400 includes one adhesive layer having a space is exemplified, but the adhesive member 400 may further include a second adhesive layer 403 having a space on the back side of the first adhesive layer 401. FIG. 17 is a schematic cross-sectional view illustrating an example of an adhesive member 400 including a second adhesive layer 403. As illustrated in FIG. 17, the adhesive member 400 includes a first base material 402 on the back side of the first adhesive layer 401, and further includes the second adhesive layer 403 on the back side of the first adhesive layer 401. The second adhesive layer 403 is an adhesive layer that is partially in contact with a base material (first base material 402) and has a space 403a between the second adhesive layer 403 and the first base material 402. In a display device 1 according to a third embodiment, interface reflection also occurs at an interface between the space 403a and the second adhesive layer 403, thereby making a boundary between a display region 1AA and a bonded portion less visible.

The second adhesive layer 403 may be divided. In other words, as illustrated in FIG. 17, the adhesive member 400 may have a region where the space 403a passes through the second adhesive layer 403 in a thickness direction. The second adhesive layer 403 includes multiple adhesive portions divided by the region that passes through the second adhesive layer 403 in the thickness direction. Focusing only on the adhesive member 400, a second base material 404 is exposed in the region where the space 403a passes through the second adhesive layer 403.

A planar shape of the second adhesive layer 403 may be similar to the planar shape of the first adhesive layer 401 exemplified in the first embodiment. Although not illustrated, the space 403a does not have to pass through the second adhesive layer 403 in the thickness direction, and the second adhesive layer 403 may have recessed portions or protruding portions on a surface on the first base material 402 side. The recessed portions or the protruding portions may have a similar shape as the shape exemplified in the first embodiment.

The second adhesive layer 403 preferably has a region that does not overlap the first adhesive layer 401 in a plan view. It is preferable that the region where the first adhesive layer 401 is placed be shifted from the region where the second adhesive layer 403 is placed. For example, as illustrated in FIG. 17, the first adhesive layer 401 is placed at a position overlapping the space 403a. In a plan view, presence of a region where the first adhesive layer 401 does not overlap the second adhesive layer 403 causes interface reflection with an air layer over an entire surface of the bonded portion where the adhesive member 400 is placed, thereby making an appearance of the bonded portion closer to an appearance of the display region 1AA. It is desirable that the region where the first adhesive layer 401 is placed and the region where the second adhesive layer 403 is placed does not overlap at all in a plan view, but an effect can be obtained even when these regions partially overlap.

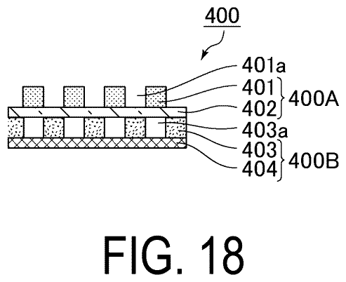

FIG. 18 is a schematic cross-sectional view illustrating an example of an adhesive member 400 including a second adhesive layer 403 and a second base material 404. As illustrated in FIG. 18, the adhesive member 400 may further include the second base material 404 on a back side of the second adhesive layer 403. The second base material 404 may be similar to a first base material 402 in terms of material, total light transmittance, thickness, and the like. The adhesive member 400 can also be said to be a layered body of a first single-sided adhesive tape 400A in which a first adhesive layer 401 is formed on the first base material 402, and a second single-sided adhesive tape 400B in which the second adhesive layer 403 is formed on the second base material 404.

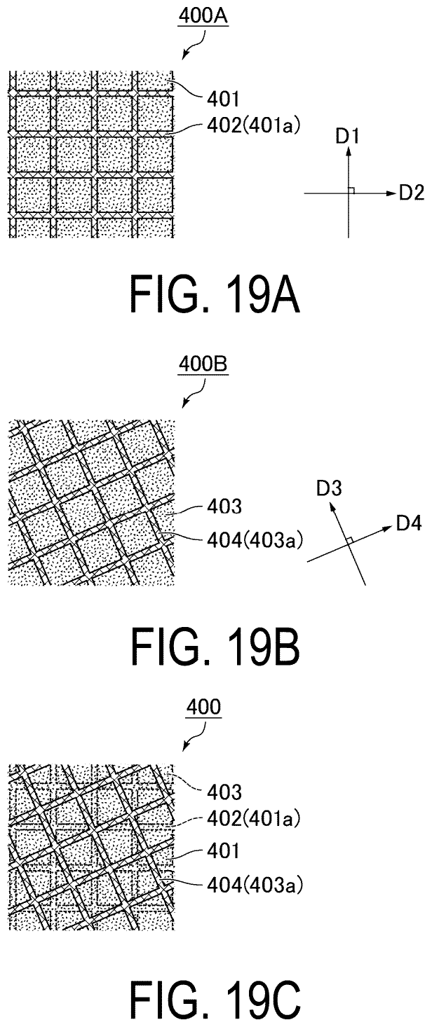

FIGS. 19A, 19B, and 19C illustrate schematic plan views describing an example of a method of layering the first adhesive layer 401 and the second adhesive layer 403 illustrated in FIG. 17 or 18. The first adhesive layer 401 includes multiple adhesive portions divided by the region that passes through the first adhesive layer 401 in the thickness direction. The first adhesive layer 401 has a space 401a provided on a surface on a front plate 110 side along a first direction D1. The second adhesive layer 403 has a space 403a provided on a surface on the front plate 110 side along a direction different from the first direction D1 in a plan view.

As illustrated in FIG. 19A, the first adhesive layer 401 may include multiple adhesive portions arranged along the first direction D1, and may further include multiple adhesive portions arranged along a second direction D2. In FIG. 19A, the space 401a is provided in a lattice pattern along the first direction D1 and the second direction D2. FIG. 19A is similar to FIG. 6 described in the first embodiment, and the arrangement, the planar shape, and the like of the adhesive portions are similar to those in the first embodiment, so that redundant description will be omitted.

As illustrated in FIG. 19B, the second adhesive layer 403 includes multiple adhesive portions divided by the region that passes through the second adhesive layer 403 in the thickness direction. The second adhesive layer 403 may include multiple adhesive portions arranged along a third direction D3, and may further include multiple adhesive portions arranged along a fourth direction D4. In FIG. 19B, the space 403a is provided in a lattice pattern along the third direction D3 and the fourth direction D4.

The fourth direction D4 is a direction different from the third direction D3, and FIG. 19B illustrates a case in which the fourth direction D4 is orthogonal to the third direction D3. The fourth direction D4 is not limited to the case in FIG. 19B, and preferably forms an angle of from 15° to 165° relative to any one of the first direction D1, the second direction D2, and the third direction D3.

In FIGS. 19A and 19B, the case in which the planar shape of the multiple adhesive portions included in the first adhesive layer 401 and the planar shape of the multiple adhesive portions included in the second adhesive layer 403 are square is illustrated, but the planar shape is not limited to a specific shape, and may be a polygon such as a square, a rectangle, or a rhombus, a circle, an ellipse, or the like.

FIG. 19C is a plan view illustrating a state in which the first adhesive layer 401 and the second adhesive layer 403 are layered. The third direction D3 is a direction different from the first direction D1, and FIG. 19C illustrates an example in which the third direction D3 forms an angle of 30° relative to the first direction D1. The third direction D3 is not limited to the case in FIG. 19C, and preferably forms an angle of from 15° to 165° relative to the first direction D1.

Being illustrated in FIG. 19C, as the first single-sided adhesive tape 400A and the second single-sided adhesive tape 400B, single-sided adhesive tapes having the same planar shape and arrangement pattern of multiple adhesive portions may be used, and one of the single-sided adhesive tapes may be rotated and layered to the other. Further, as the first single-sided adhesive tape 400A and the second single-sided adhesive tape 400B, single-sided adhesive tapes having multiple adhesive portions with different planar shapes and/or arrangement patterns may be used. With such a configuration, the positions of both the spaces can be shifted and prevented from completely overlapping, so that a portion without interface reflection with the air layer can be divided more finely in a plan view.

Further, as in the second embodiment, when the surface component of the display panel 100 and the component placed on the surface of the bezel 310 are made of the same material, the appearance of the display device 1 is further improved over the entire surface.

### Fourth Embodiment

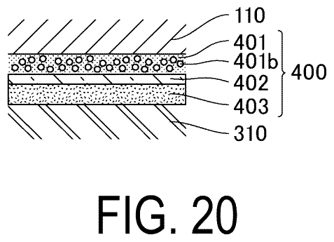

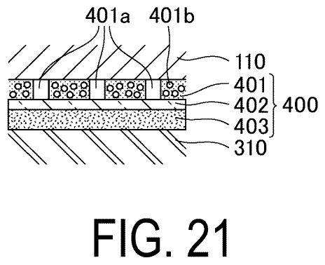

In a fourth embodiment, an adhesive member 400 includes a first adhesive layer 401 that is at least partially in contact with a front plate 110 and contains bubbles therein. FIG. 20 is a schematic cross-sectional view illustrating an example of an adhesive member 400 included in a display device according to a fourth embodiment. FIG. 21 is a schematic cross-sectional view illustrating another example of an adhesive member 400 included in a display device according to the fourth embodiment. Interface reflection occurs at an interface between air layers in the multiple bubbles 401b and an adhesive, thereby making an appearance of a bonded portion closer to an appearance of a display region 1AA.

As illustrated in FIG. 20, the display device of the fourth embodiment does not need to have a space between the first adhesive layer 401 and the front plate 110, and an entire surface of the first adhesive layer 401 may be in contact with the front plate 110. On the other hand, as illustrated in FIG. 21, the first adhesive layer 401 may be partially in contact with the front plate 110 and may have a space 401a between the first adhesive layer 401 and the front plate 110. In this case, as in the first embodiment, the adhesive member 400 may have a region where the space 401a passes through the first adhesive layer 401 in a thickness direction, or, although not illustrated, the adhesive member 400 may have recessed portions or protruding portions on a surface of the first adhesive layer 401 on a bezel 310 side, in which the space 401a does not pass through the first adhesive layer 401 in a thickness direction.

The adhesive layer having multiple bubbles 401b therein can be produced by a known method, for example, by adding a foaming agent to an adhesive composition and foaming the foaming agent.

### Fifth Embodiment

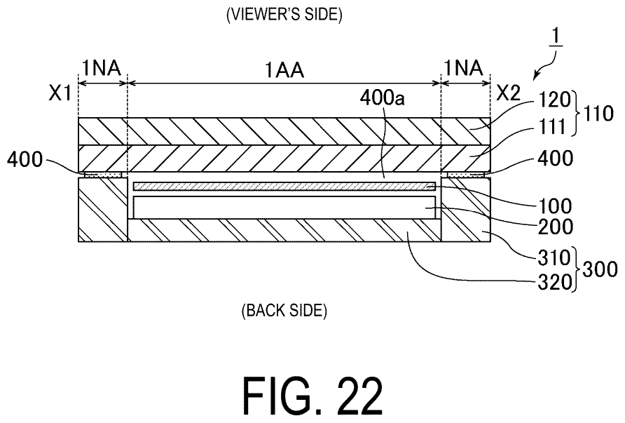

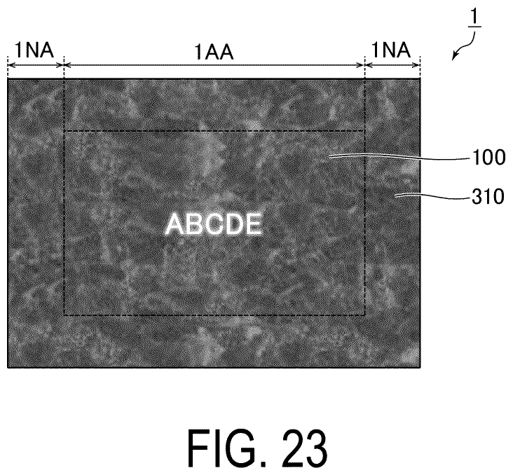

In a display device of a fifth embodiment, a front plate 110 includes a design layer 120. FIG. 22 is a schematic cross-sectional view of the display device according to the fifth embodiment. FIG. 23 is a schematic plan view of the display device according to the fifth embodiment. FIGS. 22 and 23 illustrate a case in which the design layer 120 has a marble pattern.

In a display device 1 according to the fifth embodiment, in transmissive display, light emitted from a viewing side of a display panel 100 passes through the front plate 110 and the design layer 120, and is emitted to the viewing side. The display device 1 according to the fifth embodiment, in addition to the transmissive display, can allow a viewer to see color and pattern of the design layer 120 by reflecting light (external light) incident on the display device from the viewing side.

Since the front plate 110 includes the design layer 120, the display device 1 looks just like a marble-patterned decorative plate when the display device 1 is off, and it does not look like there is the display panel 100 on a back side of the front plate 110. On the other hand, when the display device 1 is on, as illustrated in FIG. 23, an image (a string of letters ABCDE in FIG. 23) appears to emerge from the decorative plate, which provides very high design quality. By partially reducing luminance of the display device 1 to such an extent that the pattern or the like of the design layer can be seen by the viewer due to reflected light, images and the like on the display panel appears to overlap on the color of the front plate 110 and the color and pattern of the design layer 120. Note that when no design layer is provided as in the first embodiment and the like, the viewer can see the color of the front plate 110 by, for example, coloring the front plate 110.

The design layer 120 is a layer expressing a specific pattern or the like, and the pattern or the like is made visible to the viewer due to reflection of external light. The specific pattern is not particularly limited, and examples thereof include stylish geometric tones, carbon tones, marble tones, wood grain patterns, marble patterns, specific character strings, and company logos.

From the viewpoint of making a boundary between a display region 1AA and a frame region 1NA less visible, the design layer 120 is preferably placed so as to overlap the display region 1AA and the frame region 1NA of the display panel 100 in a plan view. In a plan view, the design layer 120 may be placed over an entire surface of the front plate 110, or may be placed over only part of the surface of the front plate 110. The design layer 120 is, for example, a semi-transparent picture or pattern. The specific pattern is placed in the front plate 110 as the design layer 120 by semi-transparent printing or the like. For reference, when the pattern is a wood grain pattern, a transmittance of the design layer 120 is about 60 to 80%.

The design layer 120 may have a configuration described in, for example, JP 4184711 B. The design layer 120 may be formed, for example, by printing with ink containing a glittering pigment.

The design layer 120 may be printed on a surface of a transparent base material 111 by a printing method such as gravure printing, screen printing, or ink-jet printing. Although FIG. 22 illustrates an example in which the design layer 120 is placed on the front side of the transparent base material 111, the design layer 120 may be placed on the back side of the transparent base material 111.

Typical display devices according to first to fourth comparative embodiments will be described below with reference to the drawings. In the first to fourth comparative embodiments, the adhesive member 400 illustrated in the above embodiments is not used. Note that a display panel 100R, a front plate 110R, a backlight 200R, and a bezel 310R of the first to fourth comparative embodiments can be similar to the display panel 100, the front plate 110, the backlight 200, and the bezel 310 described in the first embodiment, and thus duplicated descriptions thereof will be omitted.

### First Comparative Embodiment

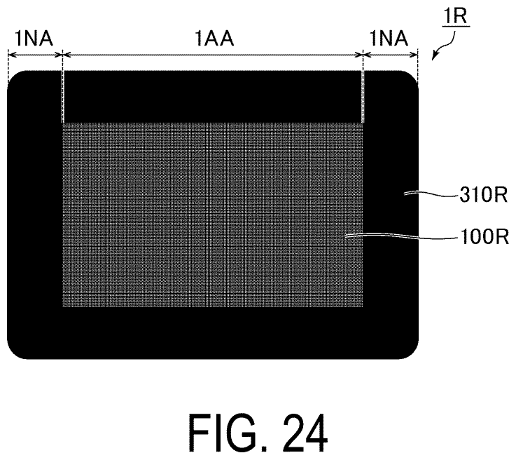

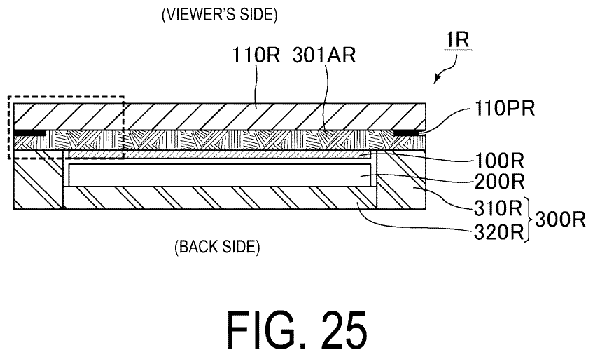

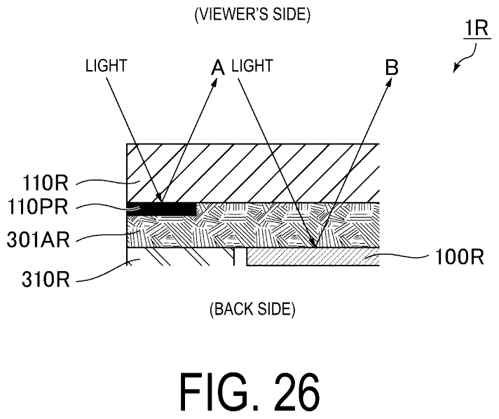

A display device 1R according to the first comparative embodiment is an example of a typical display device, and is a display device in which the display panel 100R and the front plate 110R are entirely bonded together with an optical clear adhesive sheet 301AR. FIG. 24 is a schematic plan view of the typical display device according to the first comparative embodiment. FIG. 25 is a schematic cross-sectional view of the typical display device according to the first comparative embodiment. FIG. 26 is an enlarged schematic cross-sectional view for describing reflection of external light in a region surrounded by a dotted line in FIG. 25.

In the display device 1R according to the first comparative embodiment, the display panel 100R with the backlight 200R placed on a back side thereof is stored in a housing 300R including a bezel 310R and a bottom 320R. A frame print portion 110PR is provided in a frame region 1NA of the front plate 110R using black ink or the like. The display panel 100R and the front plate 110R are bonded together with the optical clear adhesive sheet (hereinafter, also referred to as an OCA sheet) 301AR. Therefore, no air layer exists between the display panel 100R and the front plate 110R, and no interface reflection occurs between the front plate 110R and the air layer. An example of the OCA sheet 301AR is LUCIACS (registered trademark) manufactured by Nitto Denko Corporation.

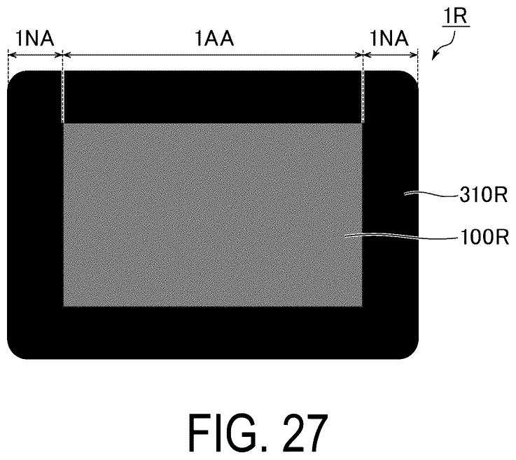

In the display device 1R of the first comparative embodiment, by making reflection characteristics of the frame print portion 110PR closer to reflection characteristics of a surface of a display region 1AA when the display device 1R is off, the frame region 1NA can be made less noticeable. In FIG. 26, A denotes a surface reflectance of the frame print portion 110PR, and B denotes a surface reflectance of the display panel 100R. By adjusting the reflectance of the frame print portion 110PR such that the surface reflectance A of the frame print portion 110PR is equal to the surface reflectance B of the display panel 100R, appearance can be improved. The display device 1R of the first comparative embodiment can have a lower reflectance of the display region 1AA than a display device according to a second comparative embodiment described below (see FIG. 27), and thus can make the display region 1AA darker as illustrated in FIG. 24, thereby making a boundary between the frame print portion 110PR and the display panel 100 less visible.

On the other hand, in addition to high costs of the OCA sheet 301AR itself, a process of bonding the front plate 110R and the display panel 100R with the OCA sheet 301AR is usually performed under vacuum, which requires expensive vacuum bonding equipment and a large amount of work time, resulting in high manufacturing costs for the display device. In addition, when bonding with the OCA sheet 301AR, air bubbles or dust may enter. Further, the display panel 100R to which the front plate 110R is bonded may warp due to temperature changes. These concerns are particularly likely to occur in large (e.g., 32 inches or larger) display devices.

The display devices of the present embodiments have a configuration in which the front plate 110 and the display panel 100 are not entirely bonded together with the OCA sheet 301AR, so that there is no risk of air bubbles or the like entering or warping of the display panel due to temperature changes, and manufacturing costs can be reduced.

### Second Comparative Embodiment

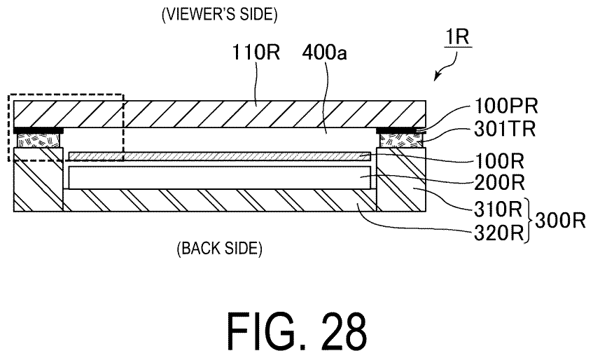

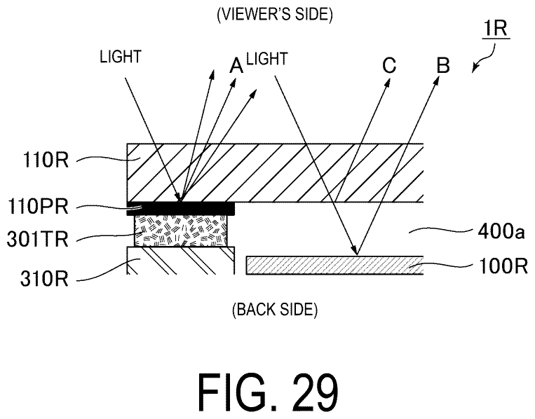

FIG. 27 is a schematic plan view of a typical display device according to the second comparative embodiment. FIG. 28 is a schematic cross-sectional view of the typical display device according to the second comparative embodiment. FIG. 29 is an enlarged schematic cross-sectional view for describing reflection of external light in a region surrounded by a dotted line in FIG. 28.

As illustrated in FIGS. 28 and 29, a display device 1R according to the second comparative embodiment includes a frame print portion 110PR on a front plate 110R, and the front plate 110R and a display panel 100R are bonded together with a double-sided tape 301TR provided in a frame region 1NA. The double-sided tape 301TR is a typical double-sided tape, and unlike the adhesive member 400 of the first embodiment, the double-sided tape 301TR is an adhesive member that has no space between the double-sided tape 301TR and the front plate 110R and contains no air bubbles therein. Note that in the display device 1R of the second comparative embodiment, the double-sided tape 301TR is located on a back side of the frame print portion 110PR, so that a bonded portion where the double-sided tape 301TR is placed is not visible from the viewing side. An example of the double-sided tape is Double-faced Adhesive Tape for Fixing of LCD Components 3800 Series, manufactured by SEKISUI CHEMICAL CO., LTD.

The display device 1R of the second comparative embodiment includes an air layer 400a between the front plate 110R and the display panel 100R, so that interface reflection occurs between the front plate 110R and the air layer 400a. In the second comparative embodiment, even when reflection characteristics of the frame print portion 110PR are made closer to reflection characteristics of a surface of a display region 1AA when not displayed, the frame print portion 110PR is more noticeable than in the first comparative embodiment because the air layer 400a exists at a position overlapping the display region 1AA.

In FIG. 29, A denotes a surface reflectance of the frame print portion 110PR, B denotes a surface reflectance of the display panel 100R, and C denotes an interface reflectance between the front plate 110R and the air layer 400a. In principle, when the surface reflectance of the frame print portion 110PR can be adjusted such that the surface reflectance A of the frame print portion 110PR is the sum of the surface reflectance B of the display panel 100R and the interface reflectance C between the front plate 110R and the air layer 400a, a boundary between the frame print portion 110PR and the display region 1AA can be less visible. However, while the surface reflection of the frame print portion 110PR is, for example, a light scattering reflection due to ink printed on the surface of the frame print portion 110PR, the interface reflection between the front plate 110R and the air layer 400a is a specular reflection, so that it is extremely difficult to bring the surface reflectance A close to the sum of the surface reflectance B and the interface reflectance C, including angular characteristics, and the bonded portion in which the frame print portion 110PR is placed is noticeable.

### Third Comparative Embodiment

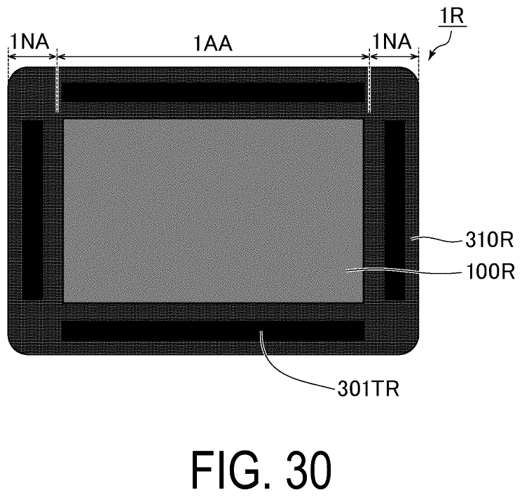

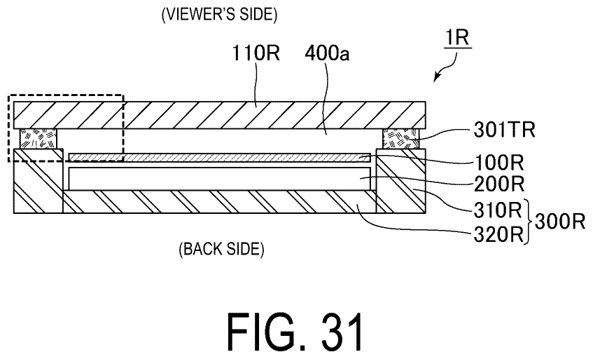

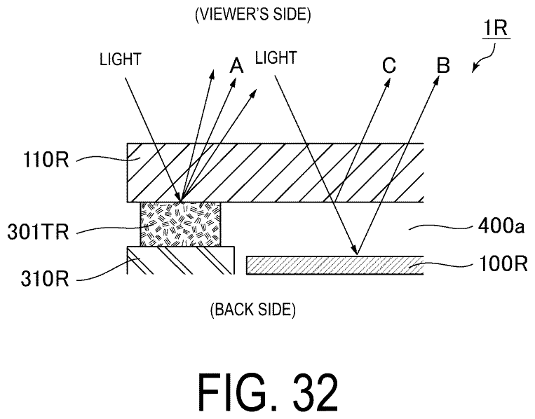

FIG. 30 is a schematic plan view of a typical display device according to a third comparative embodiment. FIG. 31 is a schematic cross-sectional view of the typical display device according to the third comparative embodiment. FIG. 32 is an enlarged schematic cross-sectional view for describing reflection of external light in a region surrounded by a dotted line in FIG. 31.

As illustrated in FIGS. 31 and 32, in a display device 1R according to the third comparative embodiment, a frame print portion 110PR is not provided on a front plate 110R, and the front plate 110R and a bezel 310R are bonded together with an adhesive member 301TR. As the adhesive member 301TR, for example, the OCA sheet 301AR illustrated in the first comparative embodiment, or the double-sided tape 301TR illustrated in the second comparative embodiment can be used. The display device 1R of the third comparative embodiment includes an air layer 400a between the front plate 110R and the display panel 100R, so that interface reflection occurs between the front plate 110R and the air layer 400a.

In the display device 1R of the third comparative embodiment, in a non-bonded portion where the double-sided tape 301TR or the like is not placed, when a tone of the bezel 310R is made similar to a tone of a display region 1AA when the display device is off, a difference in appearance between the display region 1AA and the bezel 310R is less noticeable than that illustrated in the first comparative embodiment. As the display region 1AA and the non-bonded portion of a frame region 1NA have an air layer on a back side of the front plate 110R, interface reflection between the front plate 110R and the air layer will occur. Note that in the display device 1R of the third comparative embodiment, a surface of the display panel 100R and a surface of the bezel 310R are also visible to the viewer, so that it is difficult to make the display region 1AA and the frame region 1NA look the same.

When an opaque component is used as the adhesive member 301TR, reflection occurs on a surface of the opaque component at the bonded portion. On the other hand, when a transparent component is used as the adhesive member 301TR, reflection occurs on the surface of the frame portion (bezel 310R) at the bonded portion. However, in either case, no interface reflection with the air layer occurs. Thus, reflections with different characteristics occur in the bonded portion and the non-bonded portion, resulting in a difference in appearance.

In FIG. 32, A denotes a surface reflectance of the double-sided tape 301TR, B denotes a surface reflectance of the display panel 100R, and C denotes an interface reflectance between the front plate 110R and the air layer 400a. In principle, by adjusting the reflectance of the double-sided tape 301TR (base material and adhesive layer) such that the surface reflectance A of the double-sided tape 301TR is the sum of the surface reflectance B of the display panel 100R and the interface reflectance C between the front plate 110R and the air layer 400a, a boundary between the display region 1AA and the bonded portion where the double-sided tape 301TR is placed can be less visible. However, since the surface reflection of the double-sided tape 301TR is usually a light scattering reflection, and the interface reflection between the front plate 110R and the air layer 400a is a specular reflection, it is extremely difficult to bring the surface reflectance A close to the sum of the surface reflectance B and the interface reflectance C, including angular characteristics, and the bonded portion is noticeable.

### Fourth Comparative Embodiment

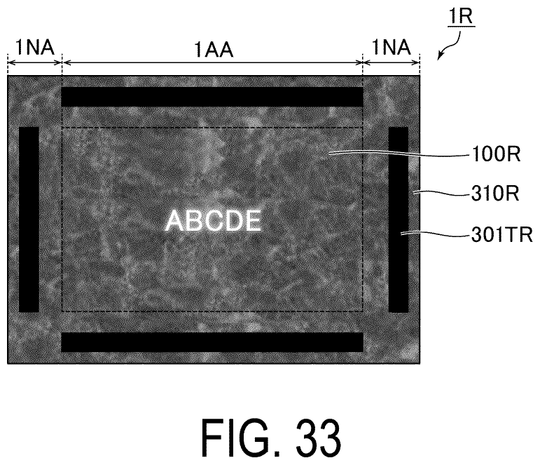

FIG. 33 is a schematic plan view of a typical display device, describing an aspect in which a front plate includes a design layer. When a front plate 110R included in a typical display device 1R includes a design layer, an appearance of a pattern when the display device 1R is off differs depending on a position of the display device 1R, resulting in poor design. To be specific, as illustrated in FIG. 33, an appearance of a bonded portion where a double-sided tape 301TR is placed on a bezel differs from an appearance of a non-bonded portion where the double-sided tape 301TR is not placed and an appearance of a display region.

In contrast to the second to fourth comparative embodiments, in the display devices according to the embodiments, the bezel 310 and the front plate 110 are bonded together using the adhesive member 400 that has the space between the adhesive member 400 and the front plate 110 or that contains air bubbles in the adhesive layer, so that the reflectance at the bonded portion where the adhesive member 400 is placed is increased. Therefore, in the display devices having the air layer 400a between the display panel 100 and the front plate 110, the appearance of the bonded portion can be made closer to the appearance of the display region 1AA.

Although the embodiments of the disclosure have been described above, the disclosure is not limited to the embodiments described above, and can be embodied in various aspects without departing from the gist thereof. The multiple constituent elements disclosed in the above embodiments can be modified as appropriate. For example, some of all the constituent elements illustrated in one embodiment may be added to the constituent elements of another embodiment, or some of all the constituent elements illustrated in one embodiment may be deleted from that embodiment. Each of the embodiments can also be combined.

The drawings mainly illustrate the corresponding constituent elements schematically in order to facilitate understanding of the disclosure, and the thickness, length, number, spacing, and the like of each of the constituent elements illustrated in the drawings may be different from the actual ones for convenience of drawing preparation. The configurations of the constituent elements illustrated in the above-described embodiments are merely examples and are not particularly limited, and it is needless to say that various modifications can be made without substantially departing from the effects of the disclosure.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. A display device comprising:
a display panel;
a housing configured to store the display panel and including a bezel placed around the display panel in a plan view;
a front plate placed on a viewing side of the display panel and overlapping the display panel and at least part of the bezel in a plan view; and
an adhesive member placed between the bezel and the front plate,
wherein the adhesive member includes a first adhesive layer, the first adhesive layer being at least partially in contact with the front plate and having a space between the first adhesive layer and the front plate, or containing bubbles inside the first adhesive layer.

2. The display device according to claim 1,
wherein the adhesive member further includes a base material placed on a bezel side of the first adhesive layer.

3. The display device according to claim 2,
wherein the adhesive member further includes a second adhesive layer on the bezel side of the base material.

4. The display device according to claim 3,
wherein the second adhesive layer is an adhesive layer being partially in contact with the base material and including a space between the second adhesive layer and the base material.

5. The display device according to claim 1,
wherein the adhesive member includes a region where the space passes through the first adhesive layer in a thickness direction.

6. The display device according to claim 4,
wherein the adhesive member includes a region where the space passes through the second adhesive layer in a thickness direction.

7. The display device according to claim 1,
wherein the first adhesive layer includes multiple recessed portions or protruding portions on a surface on a bezel side.

8. The display device according to claim 4,
wherein the first adhesive layer is provided with the space along a first direction on a surface on a front plate side, and the second adhesive layer is provided with the space along a direction different from the first direction in a plan view on a surface on the front plate side.

9. The display device according to claim 3,
wherein the second adhesive layer includes a region, the region not overlapping the first adhesive layer in a plan view.

10. The display device according to claim 1,
wherein the front plate has a total light transmittance of 5% or more.

11. The display device according to claim 1,
wherein the front plate includes a design layer.

12. The display device according to claim 1,
wherein the bezel has a reflectance of 50% or less.

13. The display device according to claim 1, comprising:
a component between the bezel and the front plate, the component being identical to a component on the viewing side of the display panel.

14. The display device according to claim 1,
wherein local dimming is possible.
